(19) United States
(12) Patent Application Publication
(10) Pub. No.: US 2019/0318978 A1
(43) Pub. Date: Oct. 17, 2019

(54) FLEXIBLE HEAT SINK FOR THERMOELECTRIC DEVICE AND FLEXIBLE THERMOELECTRIC DEVICE CONTAINING IT

(71) Applicant: KOREA ADVANCED INSTITUTE OF SCIENCE AND TECHNOLOGY, Daejeon (KR)

(72) Inventors: Byung Jin CHO, Daejeon (KR); Gyusoup LEE, Daejeon (KR); Choong Sun KIM, Daejeon (KR); Yong Jun KIM, Daejeon (KR); Seongho KIM, Daejeon (KR); Hyeongdo CHOI, Daejeon (KR)

(21) Appl. No.: 16/386,102

(22) Filed: Apr. 16, 2019

(30) Foreign Application Priority Data
Apr. 17, 2018 (KR) 10-2018-0044600

(51) Int. Cl. H01L 23/373; H01L 35/28; H01L 23/367

(52) U.S. Cl. CPC H01L 23/373; H01L 23/3677; H01L 35/28

(57) ABSTRACT

Provided is a flexible heat sink for a flexible thermoelectric device including a first metal thin film; a phase change layer including a highly conductive foam formed on the first metal thin film and a phase change material filling pores of the highly conductive foam; and a second metal thin film formed on the phase change layer. The flexible heat sink for a flexible thermoelectric device has excellent flexibility, a high heat absorption rate, and a small size for heat sinking performance.

### CROSS-REFERENCE TO RELATED APPLICATIONS

The present application claims priority to Korean Patent Application No. 10-2018-0044600 entitled “FLEXIBLE HEAT SINK FOR THERMOELECTRIC DEVICE AND FLEXIBLE THERMOELECTRIC DEVICE CONTAINING IT,” filed on Apr. 17, 2018. The entire contents of the above-listed application are hereby incorporated by reference for all purposes.

### TECHNICAL FIELD

The following disclosure relates to a flexible heat sink for a flexible thermoelectric device capable of further increasing an amount of power generation by maintaining a temperature difference of the thermoelectric device.

### BACKGROUND

A thermoelectric material refers to a material exhibiting a Peltier effect and a Seebeck effect and is applicable to active cooling, cogeneration, and the like.

The Peltier effect is a phenomenon in which holes of a p-type material and electrons of an n-type material migrate when a DC voltage is applied from the outside, causing heat generation and heat absorption at both ends of a material. The Seebeck effect refers to a phenomenon in which when heat is supplied from an external heat source, a flow of a current is formed in a material as electrons and holes migrate to cause power generation.

In recent years, thermoelectric devices which include a thermoelectric material and are formed of a flexible material to effectively absorb heat generated by various types of heat sources and which may convert energy of a heat source into electric energy at a higher conversion rate have been actively developed.

When such a thermoelectric device is used for power generation, the amount of power generated by the device increases as a temperature difference between both ends thereof increases. That is, the amount of power generated by the thermoelectric device may increase in proportion to the temperature difference between both ends.

In order to maintain the temperature difference, the thermoelectric device may typically include a heat sink, and the amount of power generation may be maintained by keeping the temperature difference for as long as possible by removing heat by the heat sink. Conventionally, a cooling fin has been used as the heat sink. The cooling fin is formed of a metal to have little flexibility, causing flexibility of the flexible device to deteriorate. In the case of enhancing performance of the cooling fin, a volume and weight of the cooling fin may increase, which may be a fatal problem in an application thereof in a wearable device.

To improve this, Korean Patent Laid-Open Publication No. 10-2016-0071829 discloses a heat sink based on a cool gel material having a high heat capacity. In this case, the heat sink is formed of a material having a high heat capacity and adopts a scheme in which the heat sink is precooled and absorbs heat for a long time to form a temperature difference in a thermoelectric device. However, with this scheme, heat may be removed for a long time but the temperature difference is not uniformly maintained, thus having a disadvantage in that a heat capacity is not substantially sufficiently utilized.

### SUMMARY

An exemplary embodiment of the present invention is directed to providing a flexible heat sink for a flexible thermoelectric device which has excellent flexibility, is small for a heat sinking effect, and has a high heat absorption rate, solving the problems of the related art heat sink of a flexible thermoelectric device which has a low heat absorption rate and a large volume and weight for a heat sinking effect.

Another exemplary embodiment of the present invention is directed to providing a flexible heat sink for a flexible thermoelectric device, which can be easily reused, has an excellent heat absorption effect even in repeated use, and has a heat absorption rate which is not lowered.

In one general aspect, a flexible heat sink for a flexible thermoelectric device includes: a first metal thin film; a phase change layer including a highly conductive foam formed on the first metal thin film and a phase change material filling pores of the highly conductive foam; and a second metal thin film formed on the phase change layer.

The flexible heat sink for a flexible thermoelectric device may include a plurality of phase change layers arranged and spaced apart from each other on the first metal thin film.

The flexible heat sink for a flexible thermoelectric device may further include an elastic portion interposed between the plurality of phase change layers arranged and spaced apart from each other.

The elastic portion may abut a side surface of each of the plurality of phase change layers and be concave from an upper side to a lower side.

An area of portions where the first metal thin film and the plurality of phase change layers abut each other may be 30% to 90% of the area of the first metal thin film.

The second metal thin film may be provided on each of the plurality of phase change layers.

One or more of the first metal thin film and the second metal thin film may have a thickness ranging from 20 to 100 μm.

The highly conductive foam may include a metal foam.

A weight ratio between the metal foam and the phase change material included in the phase change layer may be 1:1 to 1:5.

The phase change material may include one or two or more selected from among saturated hydrocarbons in a range of C₁₀ to C₃₀, fatty acids in a range of C₆ to C₃₀, fatty alcohols in a range of C₆ to C₃₀, and hydrates of metal salts.

A thickness of the phase change layer may be 2 mm to 40 mm.

In another general aspect, a flexible thermoelectric device includes the flexible heat sink for a flexible thermoelectric device according to an exemplary embodiment of the present invention.

Other features and aspects will be apparent from the following detailed description, the drawings, and the claims.

### BRIEF DESCRIPTION OF THE DRAWINGS

FIG. 1 is a cross-sectional view of a flexible heat sink for a flexible thermoelectric device according to an exemplary embodiment of the present invention.

FIG. 2 is a cross-sectional view of a flexible thermoelectric device including a flexible heat sink for a flexible thermoelectric device according to an exemplary embodiment of the present invention.

FIGS. 3A and 3B schematically illustrates a change in a flexible heat sink for a flexible thermoelectric device according to a bending direction according to an exemplary embodiment of the present invention.

FIGS. 4A, 4B and 4C are graphs illustrating open-circuit voltages of flexible thermoelectric devices according to Example and Comparative Example in an exemplary embodiment of the present invention according to a lapse of a body heat power generation reference time.

### DETAILED DESCRIPTION OF EXEMPLARY EMBODIMENTS

Hereinafter, a flexible heat sink for a flexible thermoelectric device according to the present disclosure will be described in detail with reference to the accompanying drawings. Here, technical terms and scientific terms have the same meaning as generally understood by a person skilled in the art to which the present invention pertains, unless otherwise defined, and a detailed description for a related known function or configuration considered to unnecessarily divert the gist of the present disclosure will be omitted in the following descriptions.

A flexible heat sink for a flexible thermoelectric device according to the present invention includes: a first metal thin film; a phase change layer including a highly conductive foam formed on the first metal thin film and a phase change material filling pores of the highly conductive foam; and a second metal thin film formed on the phase change layer.

The flexible heat sink for a flexible thermoelectric device according to the present invention has an excellent flexibility so as to be applicable to a flexible thermoelectric device, an excellent heat sinking effect, and a high heat absorption rate.

Recently, in order to efficiently absorb heat generated by a heat source, interest in flexible thermoelectric devices applicable to various types of heat sources has been rising, and thus, interest related to flexibility of a heat sink, essentially included in flexible thermoelectric device has also been growing. A heat sink included in a flexible thermoelectric device needs to have an excellent heat sinking effect in terms of characteristics thereof, and it is important to perform heat absorption at a high rate to maintain a temperature difference between both ends of the thermoelectric device. However, in a case where a pouch formed of a fibrous or flexible polymer material is filled with materials capable of absorbing heat, a heat conduction effect of the pouch formed of a fibrous or flexible polymer material is significantly low, thus leading to a difficulty in obtaining a heat absorption effect within a short time.

However, since the flexible heat sink for a flexible thermoelectric device according to the present invention includes a structure in which the first metal thin film, the phase change material filling a highly conductive foam, and the second metal thin film are sequentially stacked as described above, a large amount of heat may be stored in a latent heat section of the phase change material filling the highly conductive foam, while a high heat absorption effect is obtained by the metal thin film and the highly conductive foam. In addition, unlike other materials having a high heat capacity, the phase change material uses latent heat in the phase change section, and thus, a temperature at an upper portion may be uniformly maintained, rather than that heat is simply absorbed. As a result, since the temperature difference between both ends of the flexible thermoelectric device is uniformly maintained for a long period of time, high power generation efficiency may be maintained for a long time. In addition, since the phase change material is used, the flexible heat sink may be simply separated from a heat source to be reused unlike a cooling gel, may be reused by a simple method, may significantly enhance use convenience of a flexible thermoelectric device, and is not degraded in a heat absorption effect and a heat absorption rate although repeatedly used.

Preferably, the flexible heat sink for a flexible thermoelectric device according to an exemplary embodiment of the present invention may include a plurality of phase change layers arranged to be spaced apart from each other on the first metal thin film. Specifically, the plurality of the phase change layers may be arranged in a pillar shape on the first metal thin film. With such a structure, the flexible heat sink for a flexible thermoelectric device according to an exemplary embodiment of the present invention may have significantly enhanced flexibility. Specifically, when the flexible heat sink for a flexible thermoelectric device according to an exemplary embodiment of the present invention includes the plurality of pillar-shaped phase change layers spaced apart from each other, although the flexible thermoelectric device is bent, the phase change layers arranged to be spaced apart from each other are not engaged with each other to press against each other or are not subjected to tension, and thus, the phase change layers are not damaged.

Further, the flexible heat sink for a flexible thermoelectric device according to an exemplary embodiment of the present invention may further include an elastic portion interposed between the plurality of phase change layers spaced apart from each other, thus preventing a problem that a phase change material of the phase change layers absorbs heat to be liquefied and flows out of the phase change layers, absorbing a portion of an external force such as bending or curving to prevent damage to the phase change layers, and enhancing overall durability of the flexible heat sink for a flexible thermoelectric device. Further, in terms of preventing outflow of the phase change material described above, the elastic portion of the flexible heat sink for a flexible thermoelectric device according to an exemplary embodiment of the present invention may be configured to cover the entire side surfaces of the phase change layers but the invention is not limited thereto.

More preferably, in the flexible heat sink for a flexible thermoelectric device according to the exemplary embodiment of the present invention, the elastic portion may abut the side surface of the phase change layer and an upper surface of the elastic portion is concave from an upper side to a lower side. Here, the upper side in the present invention refers to a direction toward the second metal thin film, and the lower side refers to a direction toward the first metal thin film. That is, the flexible heat sink for a flexible thermoelectric device according to an exemplary embodiment of the present invention may include an elastic portion formed to be concave in the direction of the first metal thin film. With the concave elastic portion, the flexible heat sink for a flexible thermoelectric device according to an exemplary embodiment of the present invention has further enhanced flexibility.

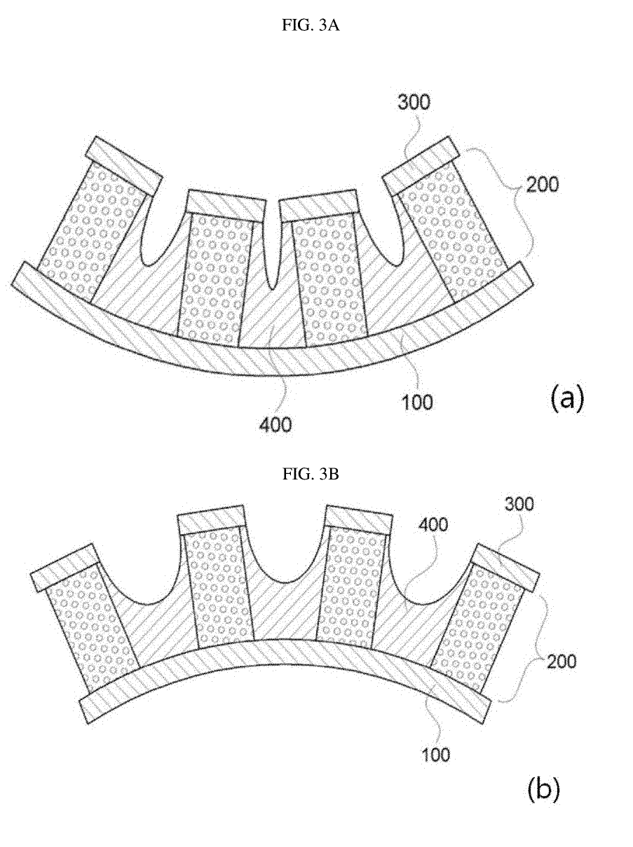

Specifically, referring to an example illustrated in FIG. 3A, when a central portion of the flexible heat sink is bent downwards as illustrated in (a), the concave elastic portions are spaced apart from each other, thereby preventing the phase change layers from pressing each other to be damaged. In addition, when the central portion of the flexible heat sink is bent upwards as illustrated in (b) of FIG. 3B, the elastic portion absorbs tension generated due to bending, thereby preventing damage to the phase change layers due to tension. Here, the concave shape of the elastic portion may refer to a curved or bent shape, but the present invention is not limited thereto.

Here, the elastic portion according to an exemplary embodiment of the present invention may be formed of any material as long as the material has elasticity. In a specific and non-limiting example, the elastic portion may include one or two or more of natural rubber, polyethylene, ethylene-vinyl acetate butyl rubber, latex, styrene-isoprene-styrene, styrene butadiene rubber, nitro butadiene rubber, nitrile butadiene rubber, styrene-ethylene-butylene-styrene, polyvinyl alcohol, and polyurethane, but the present invention is not limited thereto.

Further, in the flexible heat sink for a flexible thermoelectric device according to an exemplary embodiment of the present invention, the area of portions where the first metal thin film and the phase change layers abut each other may be 30% to 90%, and specifically, 40% to 90%, of the area of the first metal thin film. That is, the flexible heat sink for a flexible thermoelectric device according to an exemplary embodiment of the present invention may include the phase change layer in the above-mentioned area range and may include the elastic portion in a portion where the phase change layer is not formed. When the phase change layer and the elastic portion are included in the above-mentioned range, flexibility may be ensured, durability of the flexible heat sink may be improved, and deterioration of the heat sinking effect may be prevented.

In the flexible heat sink for a flexible thermoelectric device according to an exemplary embodiment of the present invention, the second metal thin films may be formed on the plurality of phase change layers, respectively. That is, the second metal thin films included in the flexible heat sink for a flexible thermoelectric device according to an exemplary embodiment of the present invention may be arranged and spaced apart from each other in the form of islands on the plurality of phase change layers arranged in the form of columns, respectively. In a case where the flexible heat sink for a flexible thermoelectric device according to an exemplary embodiment of the present invention includes the second metal thin films spaced apart from each other as described above, the effect of improving flexibility described above may be maximized and damage to the second metal thin films due to bending may be prevented.

In a case where the flexible heat sink for a flexible thermoelectric device according to an exemplary embodiment of the present invention includes the plurality of phase change layers spaced apart from each other as described above and the second metal thin films respectively formed on the phase change layers, when the flexible heat sink is applied to a flexible thermoelectric device, the first metal thin film may abut a thermoelectric material. That is, the first metal thin film abuts the thermoelectric material and the second metal thin films are exposed to the outside, whereby a temperature difference between the first metal thin film and the second metal thin films may be formed. Adopting such a structure, heat from the heat source may be absorbed by the first metal thin film to the maximum and damage to the phase change layers due to bending, or the like, may be prevented because the phase change layers are arranged apart from each other.

Here, at least one selected from the first metal thin film or the second metal thin film may have a thickness of 20 to 100 μm, and, more specifically, 30 to 80 μm. In this range, it is possible to prevent the problem that the metal thin film is easily crumpled and reduced in an area in contact with a surface of the heat source, heat absorption efficiency thereof is lowered, and flexibility is lowered due to an excessively thick metal thin film.

In the flexible heat sink for a flexible thermoelectric device according to an exemplary embodiment of the present invention, a material of the first metal thin film or the second metal thin film may include one or two or more selected from among copper, silver, gold, nickel, palladium, aluminum, zirconium, beryllium, chromium, titanium, and iron. When the first metal thin film or the second metal thin film includes two or more metals, the first metal thin film or the second metal thin film may be a thin film formed of an alloy. Alternatively, the first metal thin film or the second metal thin film may be formed by stacking different metal thin films including one or two or more of the metals described above, but the present invention is not limited thereto.

In a more specific example, the first metal thin film may further include a silver coating layer positioned on the metal thin film. When the first metal thin film further includes the silver coating layer, the first metal thin film may have excellent adhesion with the elastic portion even without any additional treatment due to naturally formed surface roughness. Here, a thickness of the coating layer may be 0.5 to 5 μm, and specifically, 1 to 3 μm, but the present invention is not limited thereto.

In the flexible heat sink for a flexible thermoelectric device according to an exemplary embodiment of the present invention, a foam having high thermal conductivity may be used as the highly conductive foam without a limitation. Specifically, in the flexible heat sink for a flexible thermoelectric device according to an exemplary embodiment of the present invention, the highly conductive foam may have porosity of 80% to 99%, and, more specifically, 95% to 99%, and, from a different perspective, foams in the range of 70 to 150 with respect to pores per inch may be used. In this range, the highly conductive foam may prevent a degradation of heat sinking efficiency due to the excessively small amount of the phase change material, while supporting the phase change material.

Further, in the flexible heat sink for a flexible thermoelectric device according to an exemplary embodiment of the present invention, the highly conductive foam may include a metal foam or a graphene foam. In the case of using the metal foam or the graphene foam, heat may be rapidly transferred to the phase change material due to accelerated heat conduction, further enhancing the heat absorption rate.

When the metal foam is used as the highly conductive foam, the metal foam may include one or more selected from among copper, nickel, titanium, chromium, aluminum, tin, vanadium, iron, cobalt, and niobium. When the metal foam includes two or more metal components, the two or more metal components may be included in the form of an alloy, but the present invention is not limited thereto.

Further, when the highly conductive foam is a metal foam, a weight ratio of the metal foam and the phase change material included in the phase change layer may be 1:1 to 1:5, and more specifically, 1:2 to 1:4.

Further, when the phase change material included in the phase change layer of the flexible heat sink for a flexible thermoelectric device according to an exemplary embodiment of the present invention is a material capable of absorbing heat emitted from a heat source using latent heat, the material may be used without a limitation. In a specific and non-limiting example, the phase change material may be one or two or more selected from among saturated hydrocarbons in the range of C₁₀ to C₃₀, fatty acids in the range of C₆ to C₃₀, fatty alcohols in the range of C₆ to C₃₀, and hydrates of metal salts. More specifically, saturated hydrocarbons in the range of C₁₂ to C₂₀ may be used, but the present invention is not limited thereto. The hydrates of metal salts may be used without a limitation as long as the hydrates have a form of a combination of common metal salts and water molecules. In a specific and non-limiting example, one or two or more selected from among Na₂SO₄·10H₂O, Na₂HPO₄·12H₂O, Na₂CO₃·10H₂O, and Na₂S₂O₃·5H₂O may be used, but the present invention is not limited thereto.

Further, the phase change material included in the flexible heat sink for a flexible thermoelectric device according to an exemplary embodiment of the present invention may be appropriately selected according to a temperature of an intended heat source. Preferably, the phase change material included in the flexible heat sink for a flexible thermoelectric device according to an exemplary embodiment of the present invention may satisfy Equation 1 below.

T_{HS}≤Tₘ≤Tₒᵤₜ [Equation 1]

In Equation 1, T_{HS} is an average temperature of a heat source, Tₘ is a melting point of phase change material, and Tₒᵤₜ is an external temperature.

That is, the melting point of the phase change material included in the flexible heat sink for a flexible thermoelectric device according to an exemplary embodiment of the present invention may fall between the temperature of the heat source and the external temperature. More specifically, the melting point of the phase change material may fall between a temperature of a junction where the flexible thermoelectric device and the flexible heat sink abut each other and an external temperature. When a flexible heat sink is manufactured by selecting a phase change material satisfying these conditions, the flexible heat sink may absorb a larger amount of heat due to latent heat based on a phase change from a solid phase to a liquid phase and maintain a sufficiently low temperature for a long period of time.

In a more specific example, in the case of a flexible thermoelectric device using a body temperature of a human body as a heat source, a phase change material having a melting point of 20° C. to 33° C., and more specifically, 23° C. to 30° C., may be used and since such a material absorbs heat emitted from the human body within the range, a temperature difference between a surface of the human body and the exterior may be maintained for a long time.

Further, a thickness of the phase change layer may vary depending on the kind of the heat source, an intended temperature maintaining time, and the like. In a specific, non-limiting example, the thickness of the phase change layer may be 2 mm to 40 mm, and more specifically, 3 mm to 20 mm, but the present invention is not limited thereto.

The present invention also provides a flexible thermoelectric device, and the flexible thermoelectric device according to the present invention includes a flexible heat sink for a flexible thermoelectric device according to an exemplary embodiment of the present invention.

Since the flexible thermoelectric device according to the present invention includes the flexible heat sink for a flexible thermoelectric device according to an exemplary embodiment of the present invention, the flexible thermoelectric device may maintain a high open-circuit voltage for a long time by performing heat absorption for a long time due to the heat sinking effect of the heat sink, without causing a degradation of flexibility of the flexible thermoelectric device itself.

The flexible thermoelectric device according to an exemplary embodiment of the present invention may have a structure in which a thermoelectric material layer including a thermoelectric material and a flexible heat sink layer for the flexible thermoelectric device are stacked, and here, the thermoelectric material layer may be stacked to abut the first metal thin film. Further, when the flexible thermoelectric device according to an exemplary embodiment of the present invention is used for actual power generation, a thermoelectric material layer may abut a heat source and the flexible heat sink layer may be stacked on the thermoelectric material layer. Through this structure, heat dissipated from the heat source may be transferred to the thermoelectric material layer to perform power generation, and heat generated by the thermoelectric material layer may be absorbed by the flexible heat sink layer, whereby a temperature difference between the heat source and the outside may be maintained.

Hereinafter, the flexible thermoelectric device and a flexible heat sink layer for a flexible thermoelectric device according to an exemplary embodiment of the present invention will be described in detail with reference to the accompanying drawings.

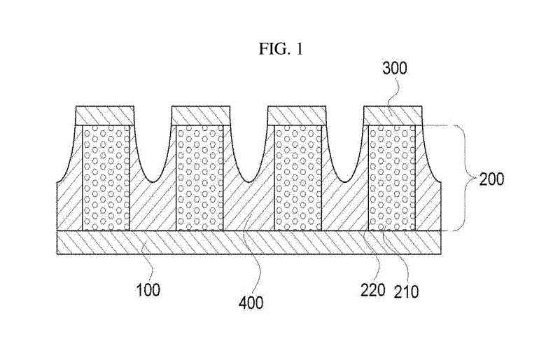

FIG. 1 is a schematic cross-sectional view of a flexible heat sink layer for a flexible thermoelectric device according to an exemplary embodiment of the present invention. Referring to FIG. 1, phase change layers 200 are arranged and spaced apart from each other in a columnar shape on a first metal thin film 100 and include a highly conductive foam 210 and a phase change material 220. An elastic portion 400 is formed between the phase change layers spaced apart from each other in the columnar shape. The elastic portion abuts side surfaces of the phase change layers and is concave from an upper side to a lower side, and thus, stress that occurs due to bending is transferred to the phase change layers, preventing damage to the phase change layers. Second metal thin films 300 are formed on the phase change layers, respectively, to prevent outflow of dissolved phase change layers.

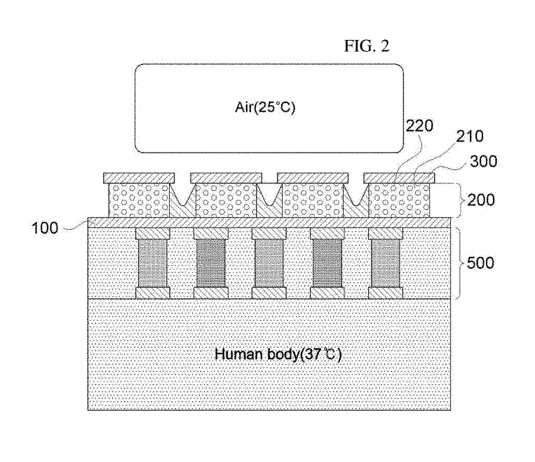

FIG. 2 is a schematic cross-sectional view of a flexible thermoelectric device according to an exemplary embodiment of the present invention. The flexible thermoelectric device according to an exemplary embodiment of the present invention may perform power generation using a body temperature as a heat source and may be provided on the skin such that the thermoelectric material layer of the flexible thermoelectric device abuts the skin. Accordingly, the thermoelectric material layer may perform power generation using heat emitted from the human body and the flexible heat sink layer which abuts the thermoelectric material layer may absorb heat, thus maintaining a temperature difference between both ends of the thermoelectric device for a long time.

FIGS. 3A and 3B is a schematic view illustrating a process of absorbing stress by an elastic layer when the flexible heat sink layer for a flexible thermoelectric device according to an exemplary embodiment of the present invention is bent. As described above, since the elastic layer is formed to be concave from the upper side to the lower side, the problem that the phase change layers press against each other to damage each other in the case of bending illustrated in of FIG. 3A may be prevented, and the elastic layer may absorb tension in the case of bending illustrated in of FIG. 3B.

Hereinafter, the present invention will be described in detail with reference to Examples. The examples described below are only for the understanding of the invention, and the present invention is not limited thereto.

### EXAMPLE 1

25 phase change layers having a size of 10 mm (width)×10 mm (length) and a height of 5 mm were arranged at equal intervals on a copper thin film (first metal thin film) having a size of 7 cm (width)×7 cm (length) and a thickness of 35 μm, and a copper thin film (second metal thin film) having a thickness of 35 μm was adhered to each of the phase change layers. Here, the phase change layers are formed by filling a copper foam with a phase change material (C₁₈H₃₈, melting point: 28° C., latent heat: 241 kJ/kg), and here, porosity of the copper foam is 98% or greater.

Thereafter, liquid phase polyurethane (vyta-flex, Smooth-on Inc.) preparations were mixed and applied to portions between the phase change layers and subsequently cured to form elastic portions. A specific shape thereof is as shown in FIG. 1, and a minimum thickness of a concave portion was formed to be 1 mm. A final average height of the flexible heat sink for a flexible thermoelectric device manufactured thusly was 5.5 mm.

A thermoelectric module was finally manufactured by bringing the first thin film of the flexible heat sink for a flexible thermoelectric device into contact with the flexible thermoelectric material layer having a thickness of 2.5 mm and an area 6.5*6.5 cm.

### COMPARATIVE EXAMPLE 1

Eleven aluminum plates having a size of 9 cm (width)×6 cm (length) and a thickness of 2 mm were vertically arranged to manufacture cooling fins, and the cooling fins were arranged on the thermoelectric material layer of Example 1 and adhered to manufacture a thermoelectric module including the cooling fins as a heat sink.

### COMPARATIVE EXAMPLE 2

In the heat sink of Example 1, only the phase change layers without the copper foam were stacked to have a height of 5 mm to manufacture a flexible heat sink, and a thermoelectric module was finally formed.

Checking of Power Generation Performance Enhancement Effect

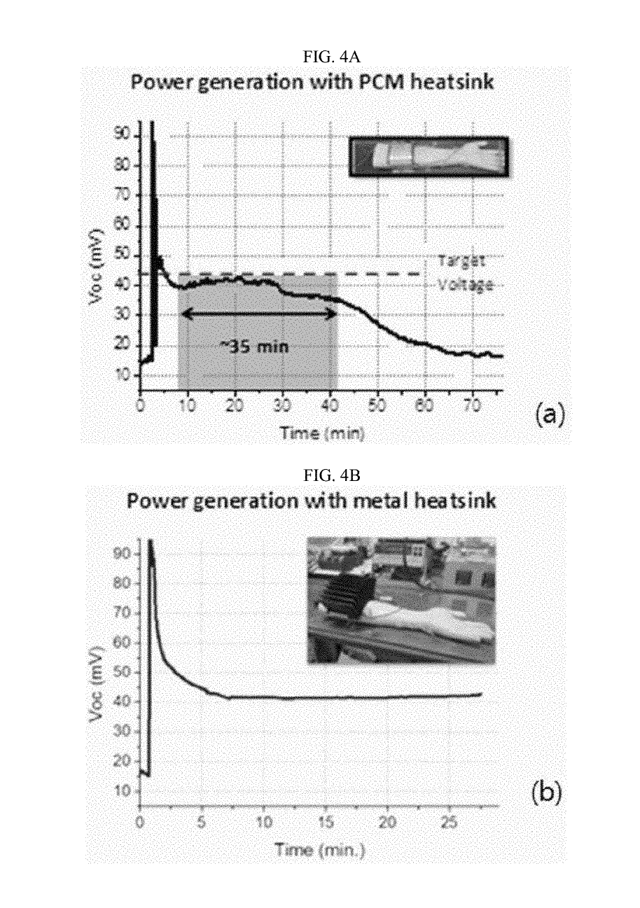

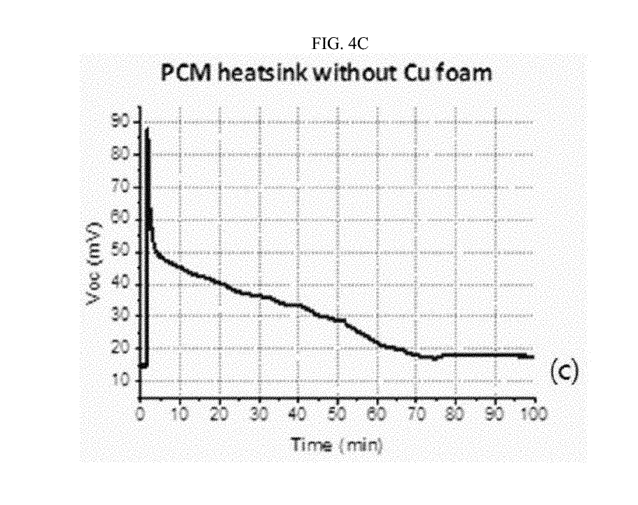

The thermoelectric module according to Example 1 and Comparative Examples 1 and 2 were attached to a human body model (37° C.) and open-circuit voltages were measured over time. FIGS. 4A-4C shows measurement results thereof. FIG. 4A corresponds to Example 1, FIG. 4B corresponds to Comparative Example 1, and FIG. 4C corresponds to Comparative Example 2.

Referring to FIG. 4A and 4C, when (a) and (c) are compared with each other, it can be seen that, without the metal foam in the heat sink, thermal conductivity of the phase change material is too low to rapidly absorb heat through a phase change, and thus, a temperature difference is not maintained, resulting in lowering of the open-circuit voltage. In contrast, in the case of using the metal foam as in the present invention, latent heat of the phase change material is fully utilized, and the open-circuit voltage is rarely lowered for about 35 minutes. Thus, it may be confirmed that the phase change material filling the metal foam absorbs heat for 35 minutes.

Also, when (a) and (b) in FIGS. 4A and 4B are compared, it can be seen that the open-circuit voltages within initial 25 minutes in Example 1 and Comparative Example 1 are about 40 mV, obtaining a similar heat sinking effect. However, since the height of the heat sink of Example 1 is 5 mm, whereas the height of the heat sink of Comparative Example 1 is 6 cm, it can be seen that space occupied by the heat sink of Comparative Example 1 is about 12 times or greater. In terms of weight, the weight of the heat sink of Example 1 is 34 g, while the weight of the heat sink of Comparative Example 1 is 340 g, and thus, it can be seen that the heat sink of Comparative Example 1 is 10 times or greater than that of the heat sink of Example 1. In spite of the difference in volume and weight, the flexible heat sink for a flexible thermoelectric device according to an exemplary embodiment of the present invention exhibits a heat sinking effect similar to that of the related art cooling fins with a significantly small volume.

As described above, since the flexible heat sink for a flexible thermoelectric device according to the present invention includes the structure in which the first metal thin film, the phase change material filling the highly conductive foam, and the second metal thin film are sequentially stacked, the flexible heat sink may have an excellent heat sinking effect for the size thereof using latent heat of the phase change material, loses a small amount of heat utilized for power generation due to the metal thin film, and has excellent flexibility. Furthermore, since the flexible heat sink for a flexible thermoelectric device according to the present invention includes the phase change material filling the highly conductive foam, the flexible heat sink may be simply cooled to be reused, may be easily reused, and may have an excellent heat absorption effect in spite of repeated use, and a heat absorption rate thereof is not lowered.

What is claimed is:

1. A flexible heat sink for a flexible thermoelectric device, the flexible heat sink comprising:
a first metal thin film; a phase change layer including a highly conductive foam formed on the first metal thin film and a phase change material filling pores of the highly conductive foam; and a second metal thin film formed on the phase change layer.

2. The flexible heat sink of claim 1, wherein the flexible heat sink for a flexible thermoelectric device includes a plurality of phase change layers arranged and spaced apart from each other on the first metal thin film.

3. The flexible heat sink of claim 2, wherein the flexible heat sink for a flexible thermoelectric device further includes an elastic portion interposed between the plurality of phase change layers arranged and spaced apart from each other.

4. The flexible heat sink of claim 3, wherein the elastic portion abuts a side surface of each of the plurality of phase change layers and is concave from an upper side to a lower side.

5. The flexible heat sink of claim 2, wherein an area of portions where the first metal thin film and the plurality of phase change layers abut each other is 30% to 90% of the area of the first metal thin film.

6. The flexible heat sink of claim 2, wherein the second metal thin film is provided on each of the plurality of phase change layers.

7. The flexible heat sink of claim 1, wherein one or more of the first metal thin film and the second metal thin film have a thickness ranging from 20 to 100 μm.

8. The flexible heat sink of claim 1, wherein the highly conductive foam includes a metal foam.

9. The flexible heat sink of claim 8, wherein a weight ratio of the metal foam and the phase change material is 1:1 to 1:5.

10. The flexible heat sink of claim 1, wherein the phase change material includes one or two or more selected from among saturated hydrocarbons in a range of C₁₀ to C₃₀, fatty acids in a range of C₆ to C₃₀, fatty alcohols in a range of C₆ to C₃₀, and hydrates of metal salts.

11. The flexible heat sink of claim 1, wherein a thickness of the phase change layer is 2 mm to 40 mm.

12. A flexible thermoelectric device comprising the flexible heat sink for a flexible thermoelectric device of claim 1.
